(19) United States
(12) Patent Application Publication
(10) Pub. No.: US 2025/0157967 A1
(43) Pub. Date: May 15, 2025

(54) SEMICONDUCTOR PACKAGE

(71) Applicant: SAMSUNG ELECTRONICS CO., LTD., Suwon-si (KR)

(72) Inventors: Ae-Nee JANG, Suwon-si (KR); Haseob SEONG, Suwon-si (KR)

(73) Assignee: SAMSUNG ELECTRONICS CO., LTD., Suwon-si (KR)

(21) Appl. No.: 18/941,796

(22) Filed: Nov. 8, 2024

(30) Foreign Application Priority Data
Nov. 9, 2023 (KR) 10-2023-0154598

(51) Int. Cl. H01L 23/00; H01L 25/18; H10B 80/00

(52) U.S. Cl. CPC H01L 24/09; H01L 24/06; H01L 24/08; H01L 25/18; H01L 2224/06131; H01L 2224/06179; H01L 2224/06181; H01L 2224/08146; H01L 2224/09515; H10B 80/00

(57) ABSTRACT

A semiconductor package includes a first semiconductor chip and a second semiconductor chip thereon. The first semiconductor chip includes upper bonding pads at an upper portion thereof. The second semiconductor chip includes lower bonding pads at a lower portion thereof. The first semiconductor chip and the second semiconductor chip are connected through direct contact between the upper bonding pads and lower bonding pads. The upper bonding pads include edge bonding pads on an edge region of the first semiconductor chip and arranged in a first direction parallel to an edge of the first semiconductor chip. The edge bonding pads include a first edge pad and a second edge pad disposed adjacent to each other. The each of the first and second edge pads is one of a power pad, a ground pad, and a dummy pad, and the first and second edge pads are of the same type.

### CROSS-REFERENCE TO RELATED APPLICATION

This U.S. non-provisional patent application is based on and claims priority to Korean Patent Application No. 10-2023-0154598 filed on Nov. 9, 2023, in the Korean Intellectual Property Office, the entire contents of which are hereby incorporated by reference.

### BACKGROUND

### 1. Field

The disclosure relates to a semiconductor package, and more specifically, to a semiconductor package including a plurality of stacked semiconductor chips.

### 2. Description of Related Art

The demand for high-performance electronic devices has increased as the electronic industry has rapidly developed. Accordingly, the need for a method of arranging a plurality of semiconductor chips to achieve high-performance has increased. Thus, a semiconductor package is been proposed in which a plurality of semiconductor chips with through electrodes are stacked in a vertical direction.

### SUMMARY

After hybrid bonding semiconductor chips in a vertical direction, a bonding void may occur between pads adjacent to an edge region of an adhesive surface of the semiconductor chips. Provided is a semiconductor package with increased reliability by preventing a conductive material from moving through the bonding void due to a potential difference between adjacent pads.

According to an aspect of the disclosure, a semiconductor package includes: a first semiconductor chip comprising upper bonding pads on an upper portion thereof; and a second semiconductor chip on the first semiconductor chip, wherein the second semiconductor chip comprises lower bonding pads on a lower portion thereof, wherein the first semiconductor chip and the second semiconductor chip are connected through contact between the upper bonding pads and the lower bonding pads, wherein the upper bonding pads comprise edge bonding pads in an edge region of the first semiconductor chip, wherein the edge bonding pads are arranged in a first direction parallel to an edge of the first semiconductor chip, wherein the edge bonding pads comprise a first edge pad and a second edge pad adjacent to each other, and wherein each of the first edge pad and the second edge pad is one of a power pad, a ground pad, and a dummy pad, and the first edge pad and the second edge pad are of a first same type.

According to an aspect of the disclosure, a semiconductor package includes: a first semiconductor chip comprising a first metal pattern, a second metal pattern, and upper bonding pads on an upper portion thereof; and a second semiconductor chip on the first semiconductor chip, wherein the second semiconductor chip comprises lower bonding pads on a lower portion thereof, wherein the first semiconductor chip and the second semiconductor chip are connected through contact between the upper bonding pads and the lower bonding pads, wherein the first metal pattern and the second metal pattern are spaced apart from each other in a first direction parallel to an edge of the second semiconductor chip, and the first metal pattern and the second metal pattern are adjacent to each other in the first direction, wherein the upper bonding pads comprise a first pad and a second pad in contact with an upper surface of the first metal pattern and an upper surface of the second metal pattern, respectively, wherein the first pad and the second pad are in an edge region of the first semiconductor chip, and wherein a first voltage is applied to the first metal pattern and the second metal pattern.

According to an aspect of the disclosure, a semiconductor package includes: a package substrate; an interposer on the package substrate; a logic chip on the interposer; and a plurality of chip stacked structures spaced apart from each other with the logic chip therebetween, wherein each of the plurality of chip stacked structures comprises: a first semiconductor chip comprising an upper insulating layer and upper bonding pads on the upper insulating layer; and a second semiconductor chip on the first semiconductor chip, wherein the second semiconductor chip comprises a lower insulating layer and lower bonding pads on the lower insulating layer, wherein the first semiconductor chip and the second semiconductor chip are bonded through contact of the upper bonding pads and the lower bonding pads and contact of the upper insulating layer and the lower insulating layer, wherein the first semiconductor chip comprises a rectangular shape, wherein the upper bonding pads comprise edge bonding pads in an edge region of the first semiconductor chip, wherein the edge bonding pads are arranged in a first direction parallel to an edge of the first semiconductor chip, wherein the edge bonding pads comprise a first edge pad and a second edge pad adjacent to each other, wherein each of the first edge pad and the second edge pad is one of a power pad, a ground pad, and a dummy pad, and the a voltage is applied to the first edge pad and the second edge pad, and wherein the edge region comprises a width of 1.5 mm or less.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a cross-sectional view of a semiconductor package according to one or more embodiments of the disclosure;

FIG. 2 is a plan view schematically showing an upper surface indicating a position of a cross-section taken along line A-A′ of a second semiconductor chip of FIG. 1;

FIG. 3 is a plan view showing pads disposed on an upper surface of a second semiconductor chip according to FIG. 2;

FIG. 4 is a cross-sectional view schematically showing a bonding portion of second semiconductor chips corresponding to a cross-section taken along line B-B′ of FIG. 3;

FIG. 5 is a cross-sectional view schematically showing a bonding portion of second semiconductor chips corresponding to a cross-section taken along line D-D′ of FIG. 3;

FIGS. 6A, 6B, and 6C are cross-sectional views showing bonding portions of second semiconductor chips corresponding to cross-sections taken along line E-E′ of FIG. 3;

FIG. 7 is an enlarged view of portion “CU1” in FIG. 3;

FIG. 8 is an enlarged view of portion “CU2” in FIG. 3;

FIG. 9 is an enlarged view corresponding to portion “CU1” in FIG. 3;

FIG. 10 is an enlarged view corresponding to portion “CU2” in FIG. 3;

FIG. 11 is a plan view schematically showing an upper surface of the semiconductor chip of FIG. 1 according to one or more embodiments;

FIG. 12 is a plan view schematically showing an upper surface of the semiconductor chip of FIG. 1 according to one or more embodiments;

FIG. 13 is a plan view schematically showing an upper surface of a bonding portion of second semiconductor chips in which a bonding void is formed;

FIG. 14 is a cross-sectional view schematically showing a bonding portion of second semiconductor chips of a semiconductor package according to a comparative example;

FIG. 15 is a plan view of a semiconductor package according to one or more embodiments of the disclosure; and

FIG. 16 is a cross-sectional view taken along line I-I′ of FIG. 15.

### DETAILED DESCRIPTION

Hereinafter, embodiments of the disclosure will be described in detail referring to the attached drawings. In the following description, like reference numerals refer to like elements throughout the specification.

As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not exclude the other elements.

Throughout the description, when a member is “on” another member, this includes not only when the member is in contact with the other member, but also when there is another member between the two members.

Herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms first, second, third, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

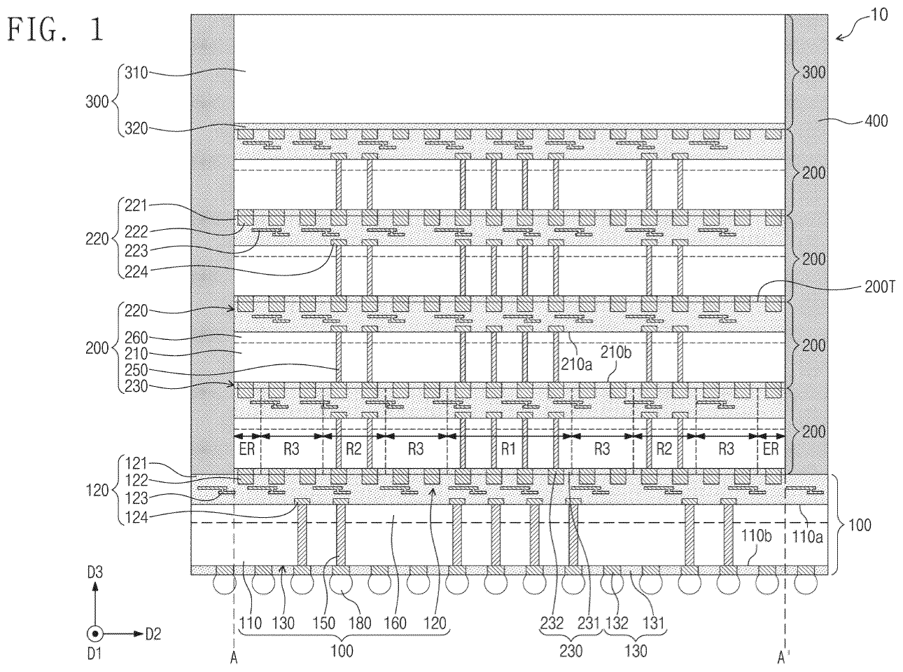

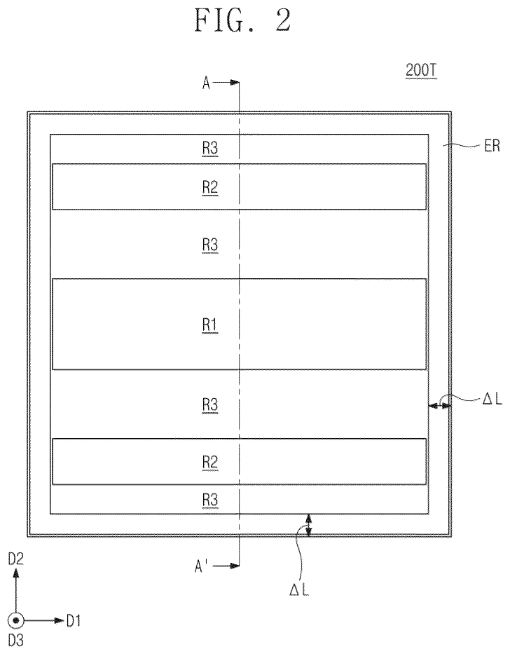

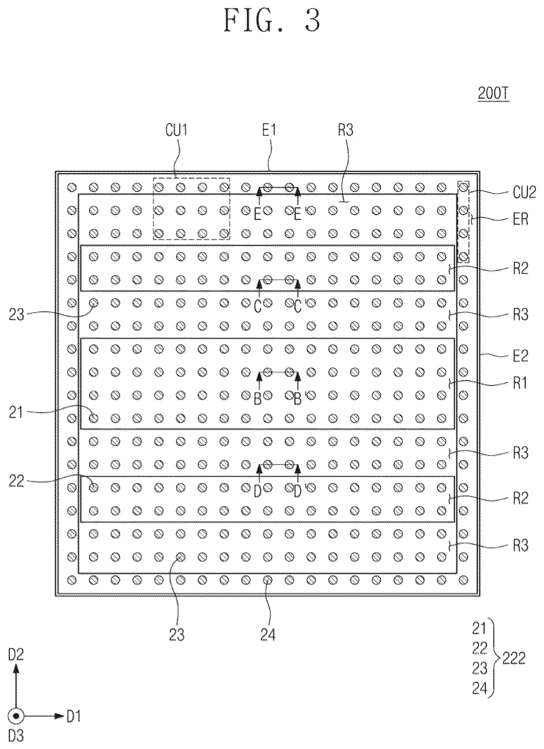

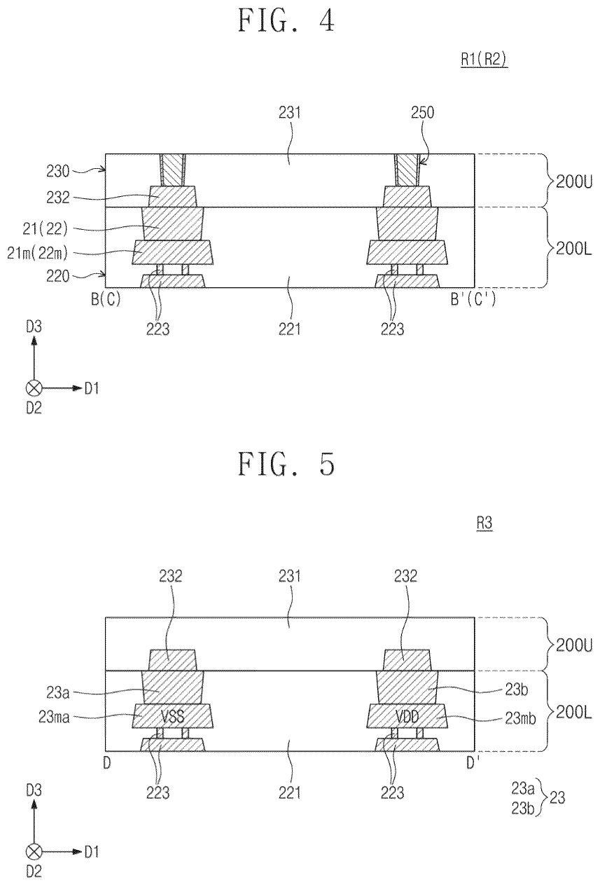

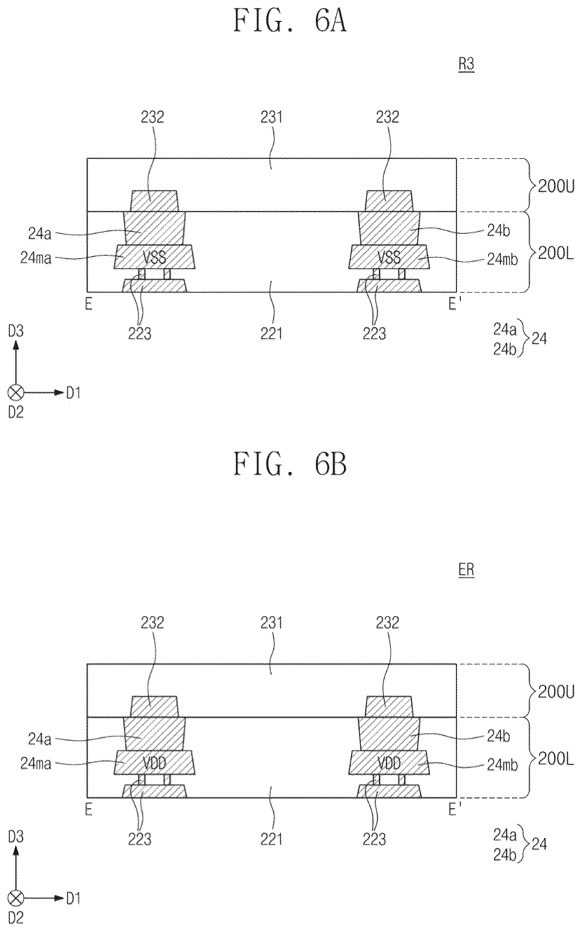

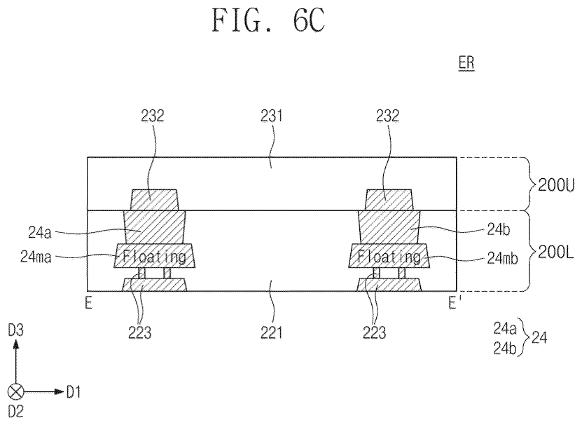

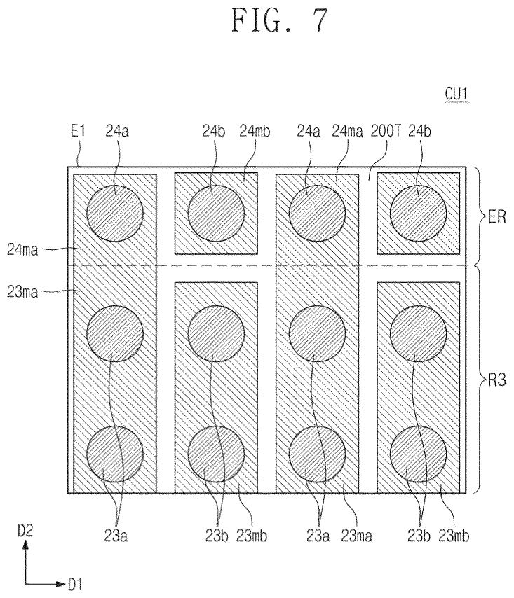

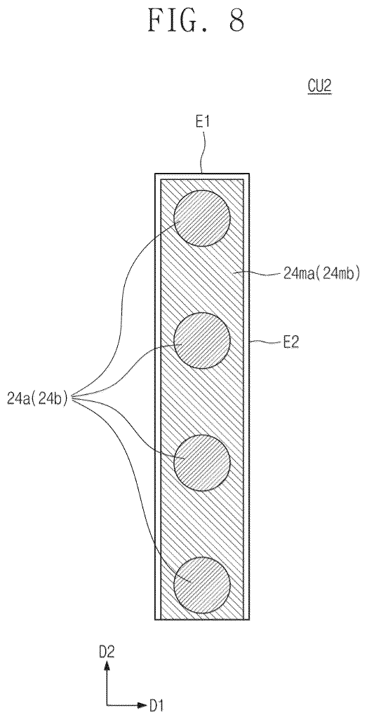

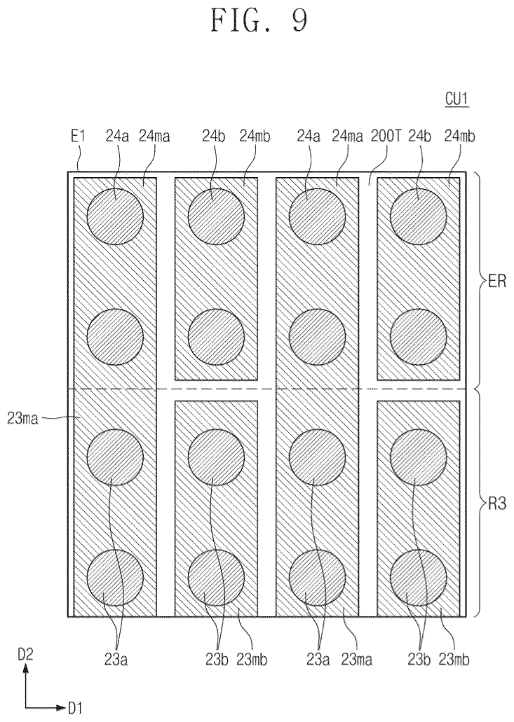

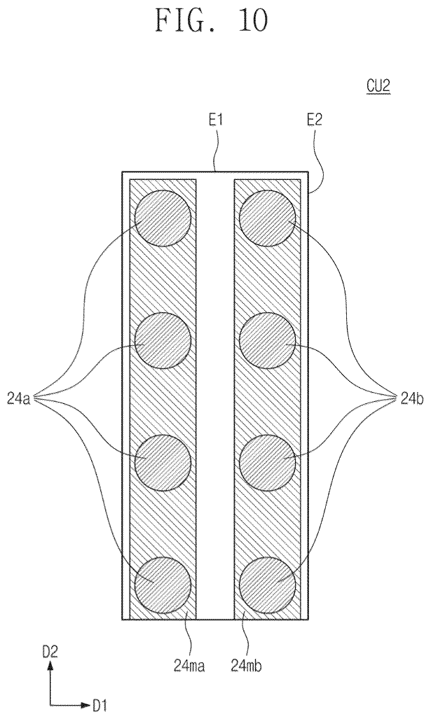

FIG. 1 is a cross-sectional view of a semiconductor package according to one or more embodiments of the disclosure. FIG. 2 is a plan view schematically showing an upper surface indicating a position of a cross-section taken along line A-A′ of a second semiconductor chip of FIG. 1. FIG. 3 is a plan view showing pads disposed on an upper surface of a second semiconductor chip according to FIG. 2. FIG. 4 is a cross-sectional view schematically showing a bonding portion of second semiconductor chips corresponding to a cross-section taken along line B-B′ of FIG. 3. FIG. 5 is a cross-sectional view schematically showing a bonding portion of second semiconductor chips corresponding to a cross-section taken along line D-D′ of FIG. 3. FIGS. 6A, 6B, and 6C are cross-sectional views showing bonding portions of second semiconductor chips corresponding to cross-sections taken along line E-E′ of FIG. 3, respectively. FIG. 7 is an enlarged view of portion “CU1” in FIG. 3. FIG. 8 is an enlarged view of portion “CU2” in FIG. 3. FIG. 9 is an enlarged view corresponding to portion “CU1” in FIG. 3. FIG. 10 is an enlarged view corresponding to portion “CU2” in FIG. 3.

Referring to FIG. 1, a semiconductor package 10 according to an embodiment may be, for example, a high bandwidth memory (HBM). The semiconductor package 10 may also be referred to as a chip stack structure 10 in this specification. The semiconductor package 10 may include a first semiconductor chip 100, second semiconductor chips 200, a dummy plate 300, and a molding structure 400.

As used herein, a direction parallel to an upper surface of the first semiconductor chip 100 or one edge of an upper surface of the second semiconductor chip 200 is defined as a first direction D1. A direction parallel to the other edge perpendicular to an edge of the upper surface of the first semiconductor chip 100 or the second semiconductor chip 200 is defined as a second direction D2. The first direction D1 and the second direction D2 intersect each other perpendicularly. A direction perpendicular to the upper surface of the first semiconductor chip 100 or the upper surface of the second semiconductor chip 200 is defined as a third direction D3.

The first semiconductor chip 100 may be disposed below the semiconductor package 10. As used herein, the first semiconductor chip 100 may also be referred to by names such as logic die, logic chip, base die, buffer chip, buffer die, and memory controller. The first semiconductor chip 100 may function as a logic chip that increases data transmission efficiency and reduces power consumption. The first semiconductor chip 100 may include a first semiconductor substrate 110, a first upper wiring layer 120, a first lower wiring layer 130, a first through electrode 150, a first circuit layer 160, and a connection terminal 180.

The first semiconductor substrate 110 may include a semiconductor material such as silicon or germanium. The first semiconductor substrate 110 may include a first upper surface 110a and a first lower surface 110b on opposite sides of the first semiconductor substrate 110. The first circuit layer 160 may include an integrated element such as a transistor.

The first upper wiring layer 120 may be disposed on the first upper surface 110a of the first semiconductor substrate 110. The first upper wiring layer 120 may include a first upper insulating layer 121, a first upper bonding pad 122, a first upper wiring pattern 123, and a first landing pad 124. The first upper insulating layer 121 may include, for example, at least one of silicon oxide (SiO₂), silicon nitride (Si₃N₄), and silicon oxynitride (SiOxNy). The first upper insulating layer 121 may be formed of a plurality of insulating layers.

The first lower wiring layer 130 may include a first lower insulating layer 131, a connection pad 132, and a first connection wiring. The first lower insulating layer 131 may include, for example, at least one of silicon oxide (SiO₂), silicon nitride (Si₃N₄), and silicon oxynitride (SiOxNy). The connection pad 132 may be provided in the plural, and some of the connection pads 132 may be in contact with the first through electrodes 150. The other connection pads 132 may be electrically connected to some of the connection pads 132 through connection wirings. One side of the connection pad 132 may be exposed from the first lower insulating layer 131. The connection terminal 180 may be disposed on one side of the exposed connection pad 132. The connection terminal 180 may be, for example, one of a solder ball, a bump, and a pillar.

The first through electrode 150 may penetrate the first semiconductor substrate 110. The first through electrode 150 may include a conductive material such as copper. A diffusion barrier pattern such as tantalum nitride (TaN), tantalum (Ta), titanium nitride (TiN), and tungsten (W) may be disposed between the first through electrode 150 and the first semiconductor substrate 110. One end of the first through electrode 150 may be directly connected to the first landing pad 124, and the other end thereof may be directly connected to the connection pad 132.

The second semiconductor chips 200 may be stacked on the first semiconductor chip 100. The second semiconductor chip 200 disposed at a lowermost portion of the second semiconductor chips 200 may be connected to the first semiconductor chip 100 through direct contact with a bonding pad. Each of the second semiconductor chips 200 may be a memory chip. The second semiconductor chip 200 may be, for example, any one of DRAM, SRAM, and NAND-FLASH. The second semiconductor chips 200 may be the same type of semiconductor chip having the same integrated circuit. As used herein, the second semiconductor chip 200 may be referred to as a core die or a core chip.

The second semiconductor chip 200 may include a second semiconductor substrate 210, a second upper wiring layer 220, a second lower wiring layer 230, a second through electrode 250, and a second circuit layer 260.

The second semiconductor substrate 210 may include a semiconductor material such as silicon or germanium. The second semiconductor substrate 210 may include a second upper surface 210a and a second lower surface 210b facing each other. The second circuit layer 260 may include an integrated element such as a transistor.

The second upper wiring layer 220 may be disposed on the second upper surface 210a of the second semiconductor substrate 210. The second upper wiring layer 220 may include a second upper insulating layer 221, a second upper bonding pad 222, a second upper wiring pattern 223, and a second landing pad 224. For example, the second upper insulating layer 221 may include at least one of silicon oxide (SiO₂), silicon nitride (Si₃N₄), and silicon oxynitride (SiOxNy). The second upper insulating layer 221 may be formed of a plurality of insulating layers. The second upper wiring pattern 223 may include a plurality of wirings and vias connected thereto. The second upper bonding pad 222 may be disposed on an upper portion of the second upper wiring layer 220.

The second lower wiring layer 230 may be disposed on the second lower surface 310b. The second lower wiring layer 230 may include a second lower insulating layer 231, a second lower bonding pad 232, and a second connection wiring. The second lower insulating layer 231 may include, for example, at least one of silicon oxide (SiO₂), silicon nitride (Si₃N₄), and silicon oxynitride (SiOxNy). The second lower bonding pad 332 may be disposed in the second lower insulating layer 331. The second lower bonding pad 332 may be provided in the plural, and some may be directly connected to the second through electrodes 250. The other the second lower bonding pads 332 may be electrically connected to the some of the second lower bonding pads 332 through second connection wirings.

The second through electrode 250 may penetrate the second semiconductor substrate 210. The second through electrode 250 may include a conductive material such as copper. A diffusion barrier pattern (e.g., tantalum nitride (TaN)) may be disposed between the second through electrode 250 and the second semiconductor substrate 210. One end of the second through electrode 250 may be directly connected to the second landing pad 224, and the other end thereof may be directly connected to some of the second lower bonding pads 232.

The second semiconductor chips 200 adjacent to each other in the third direction D3 may be connected to each other through direct contact of bonding pads. For example, an upper surface of the second upper bonding pad 222 of the second semiconductor chip 200 disposed at a lower portion may be in direct contact with a lower surface of the second lower bonding pad 232 of the second semiconductor chip 200 disposed at an upper portion. A diameter of the upper surface of the second upper bonding pad 222 may be larger than a diameter of the lower surface of the lower bonding pad 232. In contrast, the diameter of the upper surface of the second upper bonding pad 222 may be substantially the same as the diameter of the lower surface of the lower bonding pad 232. Alternatively, the diameter of the upper surface of the second upper bonding pad 222 may be smaller than the diameter of the lower surface of the lower bonding pad 232.

The dummy plate 300 may be disposed on the second semiconductor chip 200 disposed on the uppermost one of the second semiconductor chips 200. The dummy plate 300 may include a dummy substrate 310 and an adhesive insulating layer 320. The dummy substrate 310 may include a semiconductor material such as silicon or germanium. The dummy substrate 310 may be, for example, a silicon substrate. The dummy substrate 310 may not include elements such as integrated circuits, wiring patterns, or through electrodes. The adhesive insulating layer 320 may be in contact with the second upper wiring layer 220 of the second semiconductor chip 200. The adhesive insulating layer 320 may include, for example, at least one of silicon oxide (SiO₂), silicon nitride (Si₃N₄), and silicon oxynitride (SiOxNy). According to one or more embodiments, the dummy substrate 310 may include metal, and the adhesive insulating layer 320 may include a thermal interface material (TIM).

The molding structure 400 may cover the upper surface of the first semiconductor chip 100, side surfaces of the second semiconductor chips 200, and side surfaces of the dummy plate 300. The molding structure 400 may include an insulating material such as epoxy molding compound (EMC).

Referring to FIGS. 1 and 2, the second semiconductor chips 200 may include a vertical signal transmission region R1, a vertical power transmission region R2, a horizontal transmission region R3 (also referred to herein as a horizontal signal/power transmission region), and an edge region ER. Although the second semiconductor chips 200 are used as an example, the first semiconductor chip 100 also may include a vertical signal transmission region R1, a vertical power transmission region R2, a horizontal transmission region R3, and an edge region ER.

The vertical signal transmission region R1 may be disposed at a center of the second semiconductor chips 200 and may extend in the first direction D1. The vertical power transmission region R2 may be provided in the plural and the vertical power transmission regions R2 may be spaced apart in the second direction D2 with the vertical signal transmission region R1 interposed therebetween. The edge region ER refers to an region adjacent to an edge of the second semiconductor chips 200. For example, the edge region ER may mean a region in the first distance ΔL from each edge of the second semiconductor chips 200. As an example, a first distance ΔL may be 1.5 mm. The horizontal transmission region R3 refers to the remaining region of the second semiconductor chips 200 excluding the vertical signal transmission region R1, the vertical power transmission region R2, and the edge region ER. Specifically, the horizontal transmission region R3 is between the vertical signal transmission region R1 and the vertical power transmission region R2, and refers to the remaining regions of second semiconductor chips 200 excluding the vertical signal transmission region R1, vertical power transmission region R2, and edge region ER.

Referring to FIGS. 2 and 3, the second upper bonding pads 222 may be disposed on an upper surface 200T of each second semiconductor chip 200. The second upper bonding pads 222 may include signal bonding pads 21 disposed in the vertical signal transmission region R1, first power bonding pads 22 disposed in the vertical power transmission region R2, second power bonding pads 23 disposed in the horizontal transmission region R3, and edge bonding pads 24 disposed in the edge region ER. The signal bonding pads 21 and the first power bonding pads 22 may overlap the second through electrodes 250 in the third direction D3, respectively. The signal bonding pads 21 and the first power bonding pads 22 may transmit signals and power applied from the outside of the semiconductor package 10 through the second through electrodes 250 to the stacked second semiconductor chips 200.

Referring to FIGS. 3 and 4, a bonding portion of the second semiconductor chips 200 adjacent to each other in the third direction D3 in the vertical signal transmission region R1 will be described. In the second semiconductor chips 200 adjacent in the third direction D3, the second semiconductor chip 200 disposed below is called a lower second semiconductor chip 200L, and the second semiconductor chip 200 disposed above is called an upper second semiconductor chip 200U.

The second upper wiring layer 220 of the lower second semiconductor chip 200L may be in contact with the second lower wiring layer 230 of the upper second semiconductor chip 200U. The signal bonding pad 21 of the lower second semiconductor chip 200L and the second lower bonding pad 232 of the upper second semiconductor chip 200U may be in contact with each other. The second upper insulating layer 221 of the lower second semiconductor chip 200L and the second lower insulating layer 231 of the upper second semiconductor chip 200U may be in contact with each other. The second upper wiring pattern 223 may include signal wirings 21m disposed at the uppermost portion thereof. The signal wirings 21m may transmit independent signals to the signal bonding pads 21, respectively. The second through electrodes 250 may be disposed on the second lower bonding pads 232 in the vertical signal transmission region R1, respectively. The second through electrodes 250 may be in contact with the second lower bonding pads 232 in the vertical signal transmission region R1.

A cross section of the bonding portion taken along B-B′ in FIG. 3 may be similar to a cross section of the bonding portion taken along C-C′ in FIG. 3; that is, a cross section of the bonding portion of the second semiconductor chips 200 adjacent to each other in the third direction D3 in the vertical power transmission area R2. In the vertical power transmission region R2, the second upper wiring pattern 223 may include power wirings 22m disposed at the uppermost portion thereof. The power wirings 22m may transmit voltages to the power bonding pads 22, respectively. The second through electrodes 250 may be disposed on the second lower bonding pads 232 in the vertical power transmission region R2, respectively. The second through electrodes 250 may be in contact with the second lower bonding pads 232 in the vertical power transmission region R2.

Referring to FIGS. 3 and 5, a bonding portion of the second semiconductor chips 200 adjacent to each other in the third direction D3 in the horizontal transmission region R3 will be described.

The second upper wiring pattern 223 of the second semiconductor chip 200 may extend in the horizontal transmission region R3 in the second direction D2, and may include a first power wiring 23ma and a second power wiring 23mb spaced apart from each other in the first direction D1. The first power wiring 23ma and the second power wiring 23mb may be disposed at the uppermost portion of the second upper wiring pattern 223. The first power wiring 23ma and the second power wiring 23mb may include aluminum, for example. The first power wiring 23ma and the second power wiring 23mb may be electrically connected to the power wiring 22m of the vertical power transmission region R2. Different types of voltages may be applied to the first power wiring 23ma and the second power wiring 23mb, respectively. For example, a ground voltage VSS may be applied to the first power wiring 23ma, and a power supply voltage VDD may be applied to the second power wiring 23mb. The first power wiring 23ma to which the ground voltage is applied may be called a ground wiring. The second power wiring 23mb to which the power voltage is applied may be called a power wiring.

The second upper wiring pattern 223 of the horizontal transmission region R3 may be electrically connected to the second upper wiring pattern 223 of the vertical signal transmission region R1 and the vertical power transmission region R2. The second through electrodes 250 may not be disposed in the horizontal transmission region R3.

The second power bonding pads 23 may include a first power pad 23a and a second power pad 23b. The first power pad 23a may be disposed on the first power wiring 23ma, and the second power pad 23b may be disposed on the second power wiring 23mb. When the first power wiring 23ma is a ground wiring, the first power pad 23a may function as a ground pad. When the second power wiring 23mb is a power wiring, the second power pad 23b may function as a power pad.

Referring to FIGS. 3 and 6A, a bonding portion of the second semiconductor chips 200 adjacent to each other in the edge region ER in the third direction D3 will be described.

Referring to FIGS. 3 and 6A, the second upper wiring pattern 223 of the second semiconductor chip 200 may include a first metal pattern 24ma and a second metal pattern 24mb spaced apart from the edge region ER in the first direction D1. The first metal pattern 24ma and the second metal pattern 24mb may be disposed at the uppermost portion of the second upper wiring pattern 223 in the edge region ER. The first metal pattern 24ma and the second metal pattern 24mb may include aluminum, for example. The same type of voltage may be applied to each of the first metal pattern 24ma and the second metal pattern 24mb. For example, the ground voltage VSS may be applied to both the first metal pattern 24ma and the second metal pattern 24mb. Alternatively, as shown in FIG. 6B, the power supply voltage VDD may be applied to both the first metal pattern 24ma and the second metal pattern 24mb. Alternatively, as shown in FIG. 6C, a floating voltage that does not transmit power or signals may be applied to the first metal pattern 24ma and the second metal pattern 24mb. Floating means that a voltage between two points is not connected to any fixed reference (e.g. ground, power source). The second through electrodes 250 may not be disposed in the edge region ER.

The edge bonding pad 24 may include a first edge pad 24a and a second edge pad 24b. The first edge pad 24a may be disposed on the first metal pattern 24ma, and the second edge pad 24b may be disposed on the second metal pattern 24mb. The first edge pad 24a and the second edge pad 24b may be the same type of pad. For example, when a power voltage is applied to the first metal pattern 24ma and the second metal pattern 24mb, the first edge pad 24a and the second edge pad 24b may function as power pads. When a ground voltage is applied to the first metal pattern 24ma and the second metal pattern 24mb, the first edge pad 24a and the second edge pad 24b may function as a ground pad. When a floating voltage is applied to the first metal pattern 24ma and the second metal pattern 24mb, the first edge pad 24a and the second edge pad 24b may function as dummy pads.

Referring to FIGS. 3 and 7, edge bonding pads 24a and 24b of the edge region ER may be arranged in the first direction D1 or along a first edge E1. The edge bonding pads 24a and 24b may be one of a power pad, a ground pad, and a dummy pad. The edge bonding pads 24a and 24b adjacent to each other in the first direction D1 may be of the same type. Power bonding pads 23a and 23b may be disposed in the horizontal transmission region R3. The power bonding pads 23a and 23b may be arranged in the first direction D1 and the second direction D2.

A first power wiring 23ma and a second power wiring 23mb may be disposed in the horizontal transmission region R3. The first power wiring 23ma may extend to the edge region ER, and the second power wiring 23mb may not extend to the edge region ER. That is, the first metal pattern 24ma may correspond to a portion of the first power wiring 23ma. The first power pad 23a and the first edge pad 24a may be in contact with an upper surface of the first power wiring 23ma. When a first voltage is applied to the first power wiring 23ma, the first voltage may be applied to both the first power pad 23a and the first edge pad 24a.

An upper surface of the second power wiring 23mb may be in contact with the second power pad 23b, and the second edge pad 24b may not be in contact with the second power wiring 23mb. The second edge pad 24b may be in contact with the second metal pattern 24mb, and the same type of voltage as that of the first edge pad 24a may be applied. Different types of voltages may be applied to the second metal pattern 24mb and the second power wiring 23mb.

Referring to FIGS. 3 and 8, the edge bonding pads 24a and 24b of the edge region ER may be arranged in the second direction D2 or along a second edge E2. The metal pattern 24ma or 24mb extending in the second direction D2 may be disposed in the edge region ER. The edge bonding pads 24a and 24b that are in contact with the same metal pattern (24ma or 24mb) may all function as the same type of pad.

Referring to FIGS. 3 and 9, the edge bonding pads 24a and 24b of the edge region ER may be arranged in the first direction D1 and the second direction D2. The first edge pad 24a and the second edge pad 24b adjacent to each other in the first direction D1 may be the same type of pad. The first edge pads 24a adjacent to each other in the second direction D2 or the second edge pads 24b adjacent to each other in the second direction D2 may be of the same type.

An upper surface of the first power wiring 23ma may be in contact with the plurality of first edge pads 24a. The first metal pattern 24ma may be portion of the first power wiring 23ma. an upper surface of the second power wiring 23mb may not be in contact with the plurality of second edge pads 24b. An upper surface of the second metal pattern 24mb may be in contact with the plurality of second edge pads 24b. The same type of voltage as that of the first edge pads 24a may be applied to the second edge pads 24b. The same type of voltage as that of the first power wiring 23ma may be applied to the second metal pattern 24mb.

Referring to FIGS. 3 and 10, the first metal pattern 24ma and the second metal pattern 24mb may be arranged along the first edge E1 of the edge region ER and spaced apart from each other in the first direction D1. The first metal pattern 24ma and the second metal pattern 24mb may extend in the second direction D2 along the second edge E2. The same type of voltage may be applied to the first metal pattern 24ma and the second metal pattern 24mb. Accordingly, the same type of voltage may be applied to the first edge pads 24a and the second edge pads 24b arranged in the first direction D1 and the second direction D2.

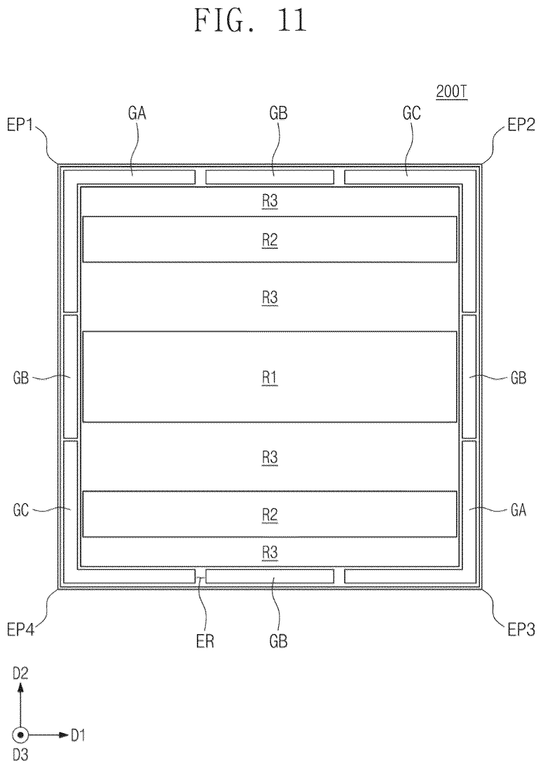

FIG. 11 is a plan view schematically showing an upper surface of the semiconductor chip of FIG. 1 according to one or more embodiments.

Referring to FIG. 11, different types of edge bonding pad groups GA, GB, and GC may be disposed in the edge region ER of the second semiconductor chip 200 according to one or more embodiments. For example, each of the edge bonding pad groups GA, GB, and GC may include the same type of edge bonding pads. For example, the first edge bonding pad group GA may be formed of ground pads, the second edge bonding pad group GB may be formed of power pads, and the third edge bonding pad group GC may be formed dummy pads.

The upper surface 200T of the second semiconductor chip 200 may have a square shape, and four vertices EP1, EP2, EP3, and EP4 may be arranged in a clockwise direction. The first vertex EP1 may be adjacent to the second vertex EP2 in the first direction D1, may be adjacent to the fourth vertex EP4 in the second direction D2, and may be adjacent to the third vertex EP3 in a diagonal direction between the first direction D1 and the second direction D2.

For example, the first edge bonding pad group GA forming an “L” shape may be disposed near the first vertex EP1 and the third vertex EP3. The third edge bonding pad group GC forming an “L” shape may be disposed near the second vertex EP2 and the fourth vertex EP4, when viewed in a plan view. The second edge bonding pad group GB may be disposed between the first edge bonding pad group GA and the third edge bonding pad group GC. A position of the second edge bonding pad group GB may be changed into the first edge bonding pad group GA and the third edge bonding pad group GC. Additionally, the first edge bonding pad group GA may replace the third edge bonding pad group GC.

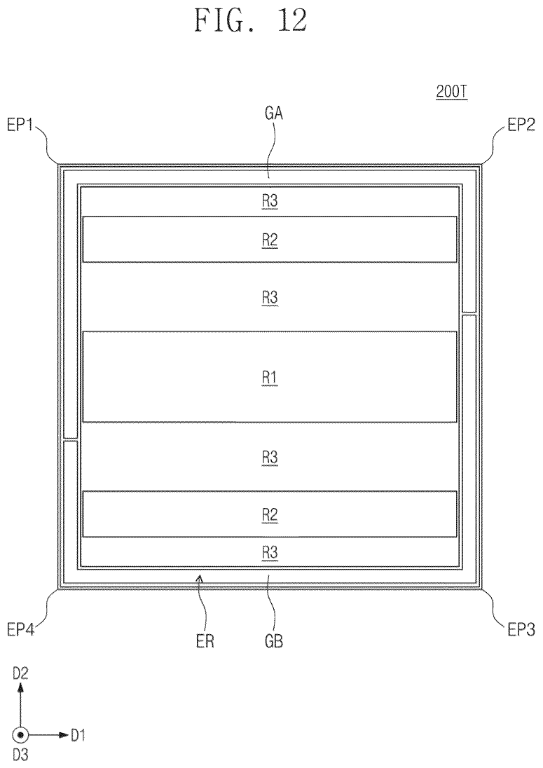

FIG. 12 is a plan view schematically showing an upper surface of the semiconductor chip of FIG. 1 according to one or more embodiments. Referring to FIG. 12, a first edge bonding pad group GA and a second edge bonding pad group GB may each be arranged in a concave-convex shape when viewed in a plan view. The first edge bonding pad group GA may be disposed between a first vertex EP1 and a second vertex EP2. A second edge bonding pad group GB may be disposed between a third vertex EP3 and a fourth vertex EP4. The first edge bonding pad group GA and the second edge bonding pad group GB may be disposed between the first vertex EP1 and a fourth vertex EP4. The first edge bonding pad group GA and the second edge bonding pad group GB may be disposed between the second vertex EP2 and the third vertex EP3.

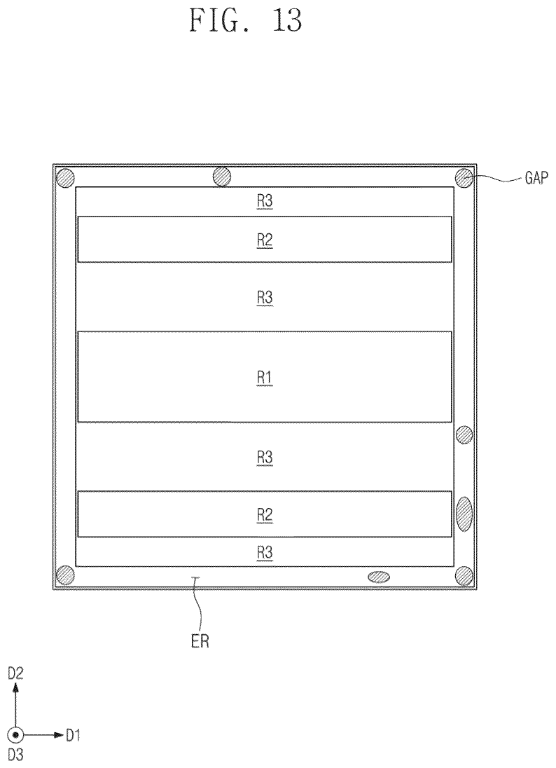

FIG. 13 is a plan view schematically showing an upper surface of a bonding portion of second semiconductor chips in which a bonding void is formed. After hybrid bonding the second semiconductor chips in the vertical direction, a bonding void GAP may occur in the edge region ER of an adhesive surface of semiconductor chips. In an edge region ER, the bonding void GAP is more likely to occur in the bonding region as compared to the other regions R1, R2, and R3.

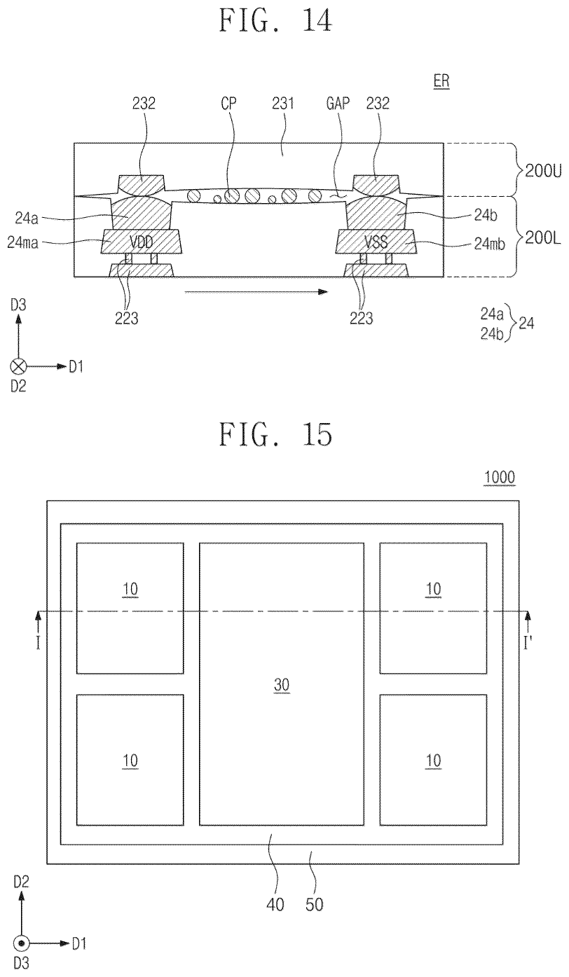

FIG. 14 is a cross-sectional view schematically showing a bonding portion of second semiconductor chips of a semiconductor package according to a comparative example. Referring to FIGS. 13 and 14, in a semiconductor package according to the comparative example, both first power wiring and second power wiring of the horizontal transmission region R3 may extend to an edge region ER. As a result, power pads and ground pads may be alternately and repeatedly disposed in the edge region ER in the first direction D1. For example, movement of a conductive material CP may occur between different types of adjacent edge pads (power pad, ground pad) disposed in the edge region through a bonding void due to a potential difference. As the conductive material CP moves, a bridge may be formed, and as a result, different types of edge pads are electrically connected, which may cause a circuit short.

According to the disclosure, the types of edge pads adjacent to each other disposed in the edge region may be configured to be the same. That is, the same voltage may be applied to edge pads adjacent to each other. As a result, no potential difference occurs between adjacent edge pads, and thus the conductive material may not move through the bonding void even when the bonding void occurs therebetween. The formation of the bridge and short circuit between adjacent edge pads may be prevented, thereby improving reliability of the semiconductor package.

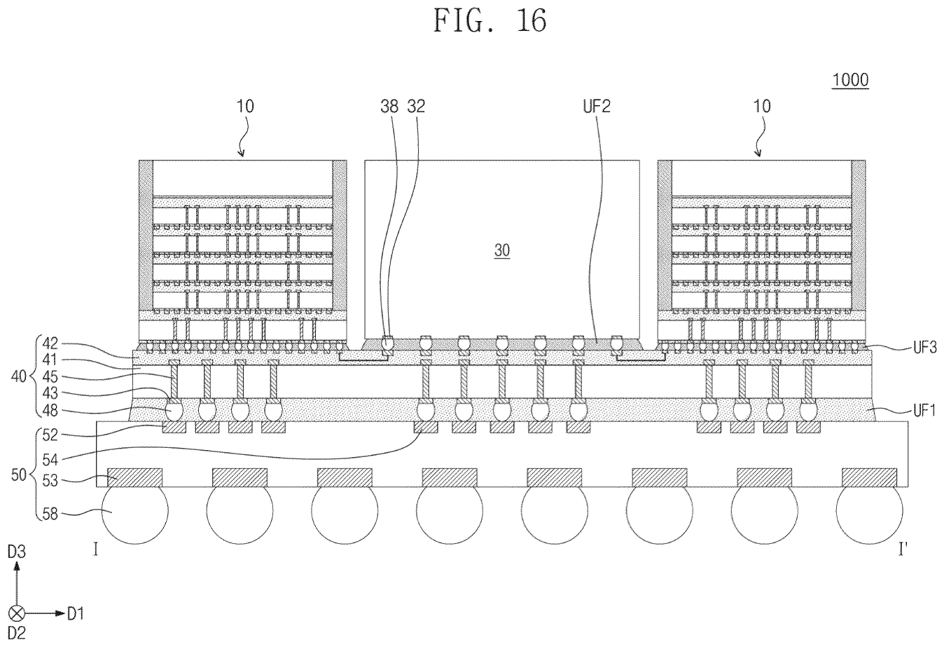

FIG. 15 is a plan view of a semiconductor package according to one or more embodiments of the disclosure. FIG. 16 is a cross-sectional view taken along line I-I′ of FIG. 15. To show components more clearly, some components in FIG. 16 are omitted from FIG. 15. Except for those described below, detailed descriptions will be omitted since they overlap with those described previously.

A semiconductor package 1000 according to one or more embodiments of the disclosure may include a package substrate 50, an interposer 40, a third semiconductor chip 30, a plurality of chip stack structures 10, and underfill patterns UF1, UF2, and UF3. The chip stack structure 10 of FIGS. 15 and 16 may correspond to the semiconductor packages 10 according to the previously described embodiments.

The package substrate 50 may be, for example, a printed circuit board (PCB). The package substrate 50 may include lower metal pads 53, first upper metal pads 52, second upper metal pads 54, metal wirings, and external connection terminals 58. The first upper metal pads 52 and the second upper metal pads 54 may be disposed on an upper portion of the package substrate 50, and the lower metal pads 53 may be disposed on a lower portion of the package substrate 50. The first upper metal pads 52 may overlap the chip stack structure 10 in the third direction D3. The second upper metal pads 54 may overlap the third semiconductor chip 30 in the third direction D3. Each of the first upper metal pads 52 and the second upper metal pads 54 may be in contact with first connection terminals 48, which will be described later. Metal wirings may connect the first upper metal pads 52 and the second upper metal pads 54 to the lower metal pads 53. The external connection terminals 58 may be disposed on the lower metal pads 53, respectively. The external connection terminals 58 may include a conductive material such as solder.

The interposer 40 may be disposed on the package substrate 50. The interposer 40 may include a third semiconductor substrate 41, third through electrodes 45, a wiring layer 42, and first connection terminals 48. The third semiconductor substrate 41 may include a semiconductor such as silicon or germanium, and may be a silicon substrate, for example. A wiring layer 42 may be disposed on the third semiconductor substrate 41. The wiring layer 42 may electrically connect the third semiconductor chip 30 and the chip stack structure 10. Each of the third through electrodes 45 may penetrate the third semiconductor substrate 41 and be connected to the first connection terminal 48 through a pad 43 or the like.

The first underfill pattern UF1 may be interposed between the interposer 40 and the package substrate 50. The first underfill pattern UF1 may include, for example, an epoxy resin composition. The first underfill pattern UF1 may fill a space between the first connection terminals 48.

The third semiconductor chip 30 and the plurality of chip stack structures 10 may be disposed on the interposer 40. As an example, the third semiconductor chip 30 may be disposed at a center of the interposer 40. With the third semiconductor chip 30 interposed therebetween, the chip stack structures 10 may be spaced apart in the first direction D1. As shown in FIG. 15, two chip stack structures 10 may be disposed adjacent to one side of the third semiconductor chip 20 and two chip stack structures 10 may be disposed adjacent to the other side of the third semiconductor chip 20. The chip stack structures 10 disposed adjacently may be spaced apart from each other in the second direction D2.

According to one or more embodiments, three chip stack structures 10 may be disposed adjacent to one side of the third semiconductor chip 20, and three chip stack structures 10 may be disposed adjacent to the other side of the third semiconductor chip 20. The chip stack structures 10 may be provided in the plural, and arrangement thereof may be variously changed.

The third semiconductor chip 30 may be a logic chip. For example, the third semiconductor chip 30 may be one of a central processing unit (CPU), a graphics processing unit (GPU), and an application specific integrated circuit (ASIC). The third semiconductor chip 30 may transmit a signal to the chip stack structure 10 or receive a signal from the chip stack structure 10. The third semiconductor chip 30 may include chip pads 32 at a lower portion thereof. Second connection terminals 38 may be disposed on the chip pads 32, respectively. The second connection terminals 38 may include a conductive material such as solder.

The second connection terminal 38 of the third semiconductor chip 30 and the connection terminal 180 of the chip stack structure 10 may be in contact with a pad on an upper surface of the interposer 40. The second underfill pattern UF2 may be disposed between the third semiconductor chip 30 and the interposer 40. The second underfill pattern UF2 may fill a space between the second connection terminals 38. The third underfill pattern UF3 may be interposed between the chip stack structure 10 and the interposer 40. The third underfill pattern UF3 may fill a space between the connection terminals 180. The second underfill pattern UF2 and the third underfill pattern UF3 may include, for example, an epoxy resin composition.

According to the disclosure, the types of the edge pads adjacent to each other disposed in the edge region may be configured to be the same. That is, the same voltage may be applied to the edge pads adjacent to each other, and the adjacent edge pads may be power pads, ground pads, or dummy pads. As a result, no potential difference may occur between the adjacent edge pads, and the conductive material may not move through the bonding void even when the bonding void occurs therebetween. The bridge formation and the short circuits between the adjacent edge pads may be prevented, thereby improving the reliability of the semiconductor package.

While embodiments are described above, a person skilled in the art may understand that many modifications and variations are made without departing from the spirit and scope of the disclosure defined in the following claims. Accordingly, the example embodiments of the disclosure should be considered in all respects as illustrative and not restrictive, with the spirit and scope of the disclosure being indicated by the appended claims.

What is claimed is:

1. A semiconductor package comprising:
a first semiconductor chip comprising upper bonding pads on an upper portion thereof; and
a second semiconductor chip on the first semiconductor chip, wherein the second semiconductor chip comprises lower bonding pads on a lower portion thereof,
wherein the first semiconductor chip and the second semiconductor chip are connected through contact between the upper bonding pads and the lower bonding pads,
wherein the upper bonding pads comprise edge bonding pads in an edge region of the first semiconductor chip,
wherein the edge bonding pads are arranged in a first direction parallel to an edge of the first semiconductor chip,
wherein the edge bonding pads comprise a first edge pad and a second edge pad adjacent to each other, and
wherein each of the first edge pad and the second edge pad is one of a power pad, a ground pad, and a dummy pad, and the first edge pad and the second edge pad are of a first same type.

2. The semiconductor package of claim 1, wherein the first edge pad and the second edge pad are adjacent to each other in the first direction.

3. The semiconductor package of claim 1, wherein the first edge pad and the second edge pad are adjacent to each other in a second direction perpendicular to the first direction.

4. The semiconductor package of claim 1,
wherein the first semiconductor chip comprises:
a vertical signal transmission region in a center portion thereof;
a vertical power transmission region between the vertical signal transmission region and the edge region; and
a horizontal transmission region between the vertical signal transmission region and the vertical power transmission region and between the vertical power transmission region and the edge region,
wherein the horizontal transmission region comprises power wirings and ground wirings alternately and repeatedly arranged in the first direction, and
wherein a power pad and a ground pad are on each of the power wirings and the ground wirings, respectively.

5. The semiconductor package of claim 4,
wherein the second semiconductor chip comprises a plurality of through electrodes,
wherein a through electrode of the plurality of through electrodes vertically overlaps the vertical signal transmission region,
wherein a through electrode of the plurality of through electrodes vertically overlaps the vertical power transmission region, and
wherein the plurality of through electrodes do not vertically overlap the horizontal transmission region and the edge region.

6. The semiconductor package of claim 1, wherein the edge region comprises a width of 1.5 mm or less.

7. The semiconductor package of claim 1, wherein a diameter of an upper surface of the upper bonding pads is larger than a diameter of a lower surface of the lower bonding pads.

8. The semiconductor package of claim 1,
wherein the first semiconductor chip further comprises a first metal pattern and a second metal pattern,
wherein the first metal pattern and the second metal pattern are in the edge region and spaced apart from each other in the first direction,
wherein the first edge pad and the second edge pad are on the first metal pattern and the second metal pattern, respectively, and
wherein a voltage is applied to the first metal pattern and the second metal pattern.

9. The semiconductor package of claim 1,
wherein the first semiconductor chip further comprises a metal pattern extending in the first direction, and
wherein both the first edge pad and the second edge pad are in contact with the metal pattern.

10. The semiconductor package of claim 1,
wherein the first semiconductor chip further comprises:
a first power wiring extending from outside the edge region into the edge region;
a second power wiring spaced apart from the first power wiring outside the edge region in a second direction perpendicular to the first direction;
a metal pattern in the edge region, wherein the metal pattern is spaced apart from the first power wiring in the first direction and spaced apart from the second power wiring in the second direction;
a first power pad on the first power wiring outside the edge region; and
a second power pad on the second power wiring outside the edge region,
wherein the first edge pad is on the first power wiring in the edge region, and
wherein the second edge pad is on the metal pattern.

11. The semiconductor package of claim 10,
wherein a first voltage is applied to the first power wiring and the metal pattern, and
wherein a second voltage different from the first voltage is applied to the second power wiring.

12. The semiconductor package of claim 10, further comprising:
a plurality of first edge pads including the first edge pad and a plurality of second edge pads including the second edge pad,
wherein the plurality of first edge pads and the plurality of second edge pads are arranged in the second direction.

13. The semiconductor package of claim 1,
wherein the edge bonding pads further comprises a first edge bonding pad group and a second edge bonding pad group,
wherein the first edge bonding pad group includes the first edge pad and the second edge pad,
wherein the second edge bonding pad group comprises a third edge pad and a fourth edge pad adjacent to each other,
wherein each of the third edge pad and the fourth edge pad is one of a power pad, a ground pad, and a dummy pad, and
wherein the third edge pad and the fourth edge pad are of a second same type different from the first same type.

14. The semiconductor package of claim 13, wherein at least one of the first edge bonding pad group and the second edge bonding pad group comprises edge pads arranged in an “L” shape with respect to a vertex of the first semiconductor chip.

15. The semiconductor package of claim 13, wherein the edge pads of the first edge bonding pad group are arranged in a concave shape and the edge pads of the second edge bonding pad group are arranged in a convex shape along edges of the first semiconductor chip.

16. A semiconductor package comprising:
a first semiconductor chip comprising a first metal pattern, a second metal pattern, and upper bonding pads on an upper portion thereof; and
a second semiconductor chip on the first semiconductor chip, wherein the second semiconductor chip comprises lower bonding pads on a lower portion thereof,
wherein the first semiconductor chip and the second semiconductor chip are connected through contact between the upper bonding pads and the lower bonding pads,
wherein the first metal pattern and the second metal pattern are spaced apart from each other in a first direction parallel to an edge of the second semiconductor chip, and the first metal pattern and the second metal pattern are adjacent to each other in the first direction,
wherein the upper bonding pads comprise a first pad and a second pad in contact with an upper surface of the first metal pattern and an upper surface of the second metal pattern, respectively,
wherein the first pad and the second pad are in an edge region of the first semiconductor chip, and
wherein a first voltage is applied to the first metal pattern and the second metal pattern.

17. The semiconductor package of claim 16, wherein the first voltage is a power voltage, a ground voltage, or a floating voltage.

18. The semiconductor package of claim 16,
wherein the first semiconductor chip further comprises a power wiring outside the edge region,
wherein the power wiring is spaced apart from the second metal pattern in a second direction perpendicular to the first direction, and is spaced apart from the first metal pattern in the first direction,
wherein a vertical level of the power wiring is substantially the same as a vertical level of each of the first metal pattern and the second metal pattern, and
wherein a second voltage different from the first voltage is applied to the power wiring.

19. The semiconductor package of claim 16, wherein the edge region comprises a width of 1.5 mm or less.

20. A semiconductor package comprising:
a package substrate;
an interposer on the package substrate;
a logic chip on the interposer; and
a plurality of chip stacked structures spaced apart from each other with the logic chip therebetween,
wherein each of the plurality of chip stacked structures comprises:
a first semiconductor chip comprising an upper insulating layer and upper bonding pads on the upper insulating layer; and
a second semiconductor chip on the first semiconductor chip, wherein the second semiconductor chip comprises a lower insulating layer and lower bonding pads on the lower insulating layer,
wherein the first semiconductor chip and the second semiconductor chip are bonded through contact of the upper bonding pads and the lower bonding pads and contact of the upper insulating layer and the lower insulating layer,
wherein the first semiconductor chip comprises a rectangular shape,
wherein the upper bonding pads comprise edge bonding pads in an edge region of the first semiconductor chip,
wherein the edge bonding pads are arranged in a first direction parallel to an edge of the first semiconductor chip,
wherein the edge bonding pads comprise a first edge pad and a second edge pad adjacent to each other,
wherein each of the first edge pad and the second edge pad is one of a power pad, a ground pad, and a dummy pad, and the a voltage is applied to the first edge pad and the second edge pad, and
wherein the edge region comprises a width of 1.5 mm or less.
